(19) United States
(12) Patent Application Publication
(10) Pub. No.: US 2005/0269603 A1
(43) Pub. Date: Dec. 8, 2005

(54) Flexible printed circuit film

(76) Inventor: Nam-Soo Kang, Ansan-si (KR)

Correspondence Address: MCGUIREWOODS, LLP, 1750 TYSONS BLVD, SUITE 1800, MCLEAN, VA, 22102, US

(21) Appl. No.: 11/131,295

(22) Filed: May 18, 2005

(30) Foreign Application Priority Data
May 14, 2004 (KR) 10-2004-0034291
May 19, 2004 (KR) 10-2004-0035558

(51) Int. Cl. H01L 31/062; H01L 31/113

(52) U.S. Cl. 257/291

(57) ABSTRACT

A flexible printed circuit film has a first wiring and a second wiring. The first wiring is formed on a layer other than where the second wiring is formed, and crosses the second wiring almost at right angle 90°. This structure of the flexible printed circuit film enables to make electronic devices lighter, smaller, and denser than the conventional one. This structure of the flexible printed circuit film also reduces the interferences among the signals coming from the flexible printed circuit film.

### CROSS-REFERENCE OF RELATED APPLICATION

The present application claims priority from Korean Patent Application No. 2004-003555, filed on May 19, 2004, the disclosure of which is hereby incorporated by reference in its entirety.

### BACKGROUND OF THE INVENTION

1. Field of the Invention

The present invention relates to a flexible circuit film.

2. Description of the Related Art

A flexible printed circuit film (FPCF) has been used in cameras. These days, the flexible printed circuit film is used in computer hard disc drive, a floppy disk drives, a copy machines and a printer. Recently, the flexible printed circuit film is used in a liquid crystal displays (LCD) connecting a printed circuit board (PCB) to an LCD panel. As more products use the FPCF, the more commercially important the FPCF becomes.

An LCD panel comprises a thin film transistor (TFT) array substrate, a color filter (CF) substrate and a liquid crystal (LC) layer filled in a gap between the TFT array substrate and the CF substrate. The TFT array substrate comprises a gate line, a data line, a thin film transistor and a pixel electrode. The CF substrate comprises a color filter and a common electrode. A TFT is a switching element that transfers or blocks image signals according to the gate signals transferred through the gate lines. An image signals is transferred through the data lines. The gate lines receives gate signals from a gate driving integrated circuit (IC). The data lines receives data signals from a data driving IC.

The gate IC and the data IC are connected to the TFT substrate. One of methods connecting them is using a tape carrier package (TCP). Another method is a chip on glass (COG). The TCP attaches a circuit tape to the TFT substrate. The circuit tape carries a gate IC on it. The COG forms the gate IC directly on the TFT substrate.

The TCP is easy to produce and provides a high yield. The COG reduces the material costs and makes a slim and compact LCD. A control unit on a printed circuit board (PCB) generates signals to apply to the driving ICs through an FPCF.

Recently, electronic devices are smaller, lighter, and more integrated than they were. The FPCF needs to meet requirement for those devices. The FPCF should be attached well to electronic devices. The FPCF should have good thermal resistance. Furthermore, the signals transferred through the FPCF should not interfere each other.

Input end portion of the conventional FPCF has integrated wirings. Densely populated wires may twist among themselves, which may cause interference among the signal.

### SUMMARY OF THE INVENTION

A FPCF comprises a flexible insulating film, a wiring pattern, an input end, an output end, and a connection portion that connects the input end and the output end. The connection portion is a film with a roughly rectangular shape. Thus the connection portion has a longitudinal direction and a transversal direction. First and second transversal wirings are formed at the input end. The first wirings are formed on a layer different from some of the second wirings. Third transversal wirings are formed on the same layer as the first transversal wirings and at the output end. In the connection portion, first longitudinal wirings are formed on a layer different from the first transversal wirings, and second longitudinal wirings that are electrically connected to the second transversal wirings are formed on a layer different from the first transversal wirings. The first transversal wirings and the third transversal wirings are crossing a portion of the first longitudinal wirings.

### BRIEF DESCRIPTION OF THE DRAWINGS

FIG. 1 shows the whole area of a flexible printed circuit film and its wirings of one embodiment of the present invention.

FIG. 2 shows a portion of the wirings of an embodiment of the present invention.

FIG. 3 shows a portion of one layer of the embodiment of the FIG. 2.

FIG. 4 shows a portion of another layer of the embodiment of the FIG. 2.

FIG. 5 shows a portion of the wirings of an embodiment of the present invention.

FIG. 6 shows a portion of one layer of the embodiment of the FIG. 5.

FIG. 7 shows a portion of another layer of the embodiment of the FIG. 5.

FIG. 8 shows details of the center portion of the FPCF of an embodiment of the present invention.

FIG. 9 shows the wirings of one layer of the FPCF of the FIG. 8.

FIG. 10 shows wirings of another layer of the FPCF of the FIG. 8.

FIG. 11 shows the wirings of an end portion of the FPCF of an embodiment of the present invention.

FIG. 12 shows an example of an FPCF used in a TFT LCD.

FIG. 13 shows a cross-sectional view of X-X′ in FIG. 12.

### DETAILED DESCRIPTION OF THE PREFERRED EMBODIMENTS

An FPCF comprises an insulation film, wirings attached to the insulation film with adhesive or without adhesive, and a cover film that covers the wirings for insulation.

An embodiment of the present invention provides an FPCF reducing interference among the signals transferring through the FPCF. One embodiment of the present invention provides two distinctive wirings printed on FPCF 10, a longitudinal wiring 17 and a transversal wiring 15. The two distinctive wirings are formed on different layers of the film. The longitudinal wirings 17 crosses over the transversal wiring 15 at substantially right angle 90°) in the connection portion of the FPCF. This minimizes interference of signals transferring through the wirings. An embodiment of the present invention also provides an FPCF whose wirings are not integrated in an input area.

The details of the present invention will be described hereinafter with reference to the accompanying drawings, in which preferred embodiments of the invention are shown. The present invention may, however, be embodied in many different forms and should not be construed as limited to the embodiments set forth herein.

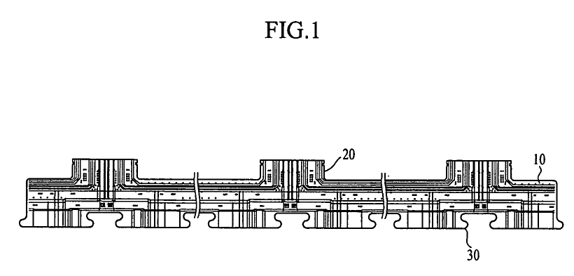

In FIG. 1, the wirings of the FPCF are formed in a transversal direction at the input end, and connected to the longitudinal direction. The longitudinal wirings are connected to the transversal wirings in the output end.

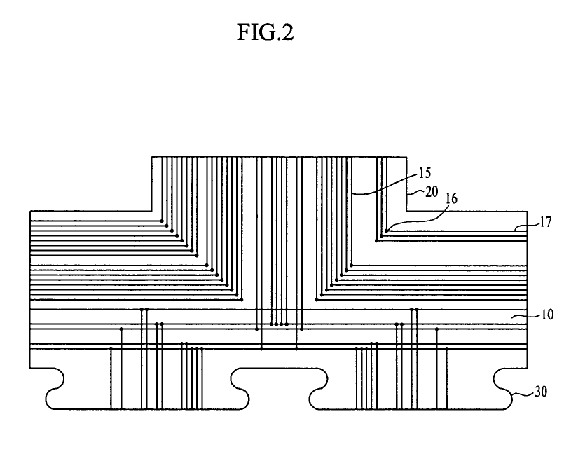

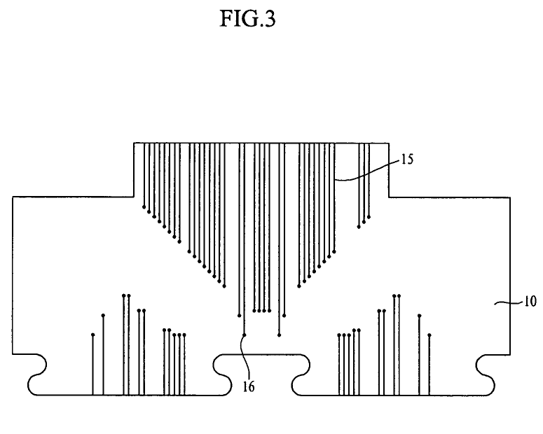

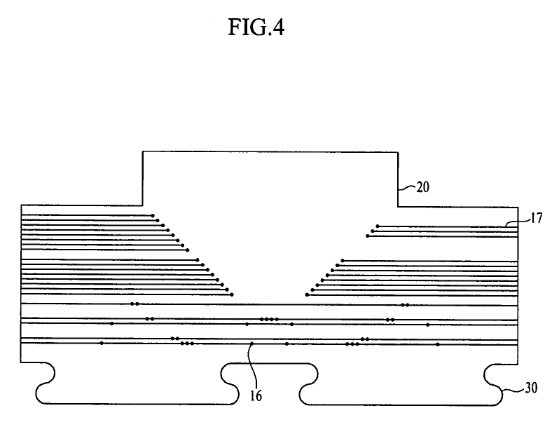

FIG. 2 shows an FPCF of an embodiment of the present invention. Transversal wirings 15 are formed in the input portion 20 and the output portion 30. Longitudinal wirings are formed in the connection portion. First transversal wirings run from an input end portion to the connection portion and are electrically coupled to the longitudinal wirings via holes 16. The longitudinal wirings run to the longitudinal direction in the connection portion and electrically coupled to the second transversal wirings via holes 16. The second transversal wirings run from the longitudinal wirings to an output end portion. The transversal wirings are formed on a different layer from the layer the longitudinal wirings are formed and substantially right angle from the longitudinal wirings, which minimizes interference among signals transferring through the FPCF. FIGS. 3 and 4 show that the transversal wirings are formed on one layer and the longitudinal wirings are formed on another layer.

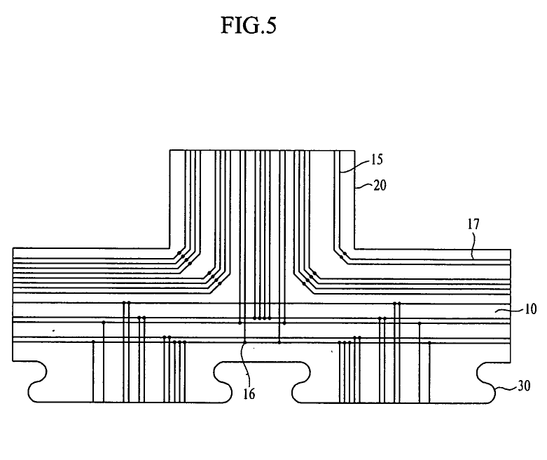

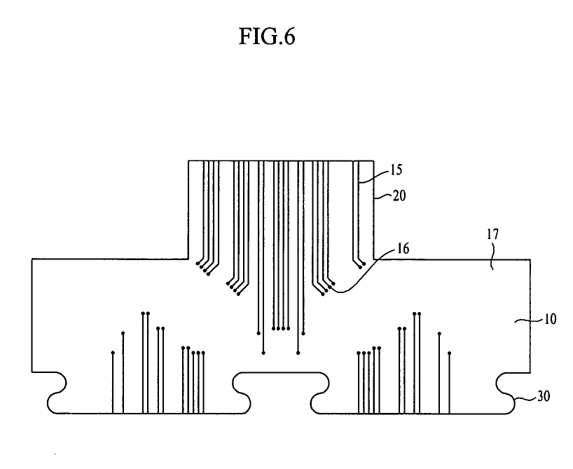

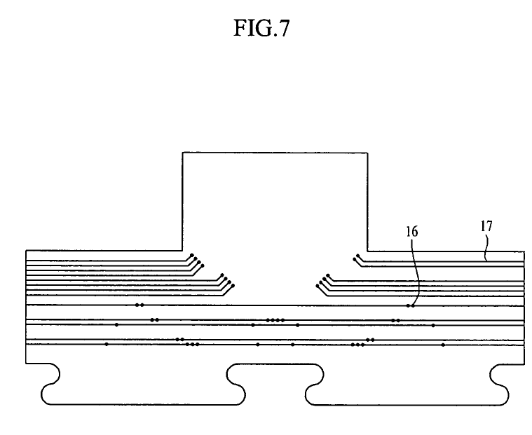

FIGS. 5, 6 and 7 show another embodiment of the present invention. Some wiring may be better for interference being inclined from the transversal wirings than bending perpendicularly, especially when the bending area is far enough from other wirings.

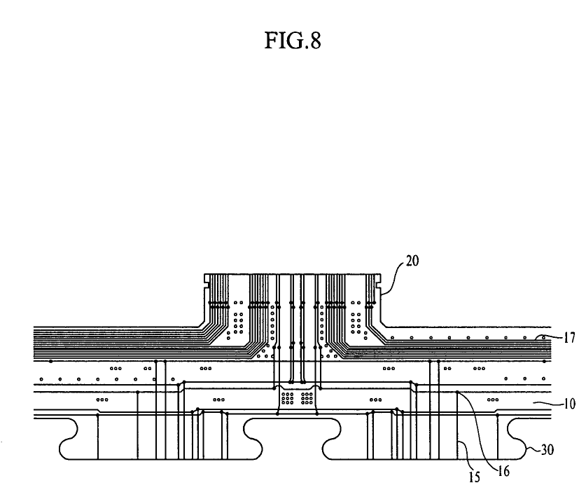

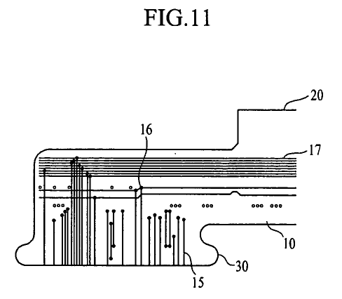

As shown in FIGS. 8, 9, 10, 11, and 13, the transversal wirings (15) are formed in the input portion (20). The input portion wirings 15 can be grouped into two. First group of transversal wirings are located at the center of the input end portion, and extend straight in a transversal of the connection portion. Second group of transversal wirings position at both ends of the input end portion, and extend straight and later bent to a longitudinal direction at the connection portion. The first group of transversal wirings is electrically coupled to the longitudinal wirings via holes 16.

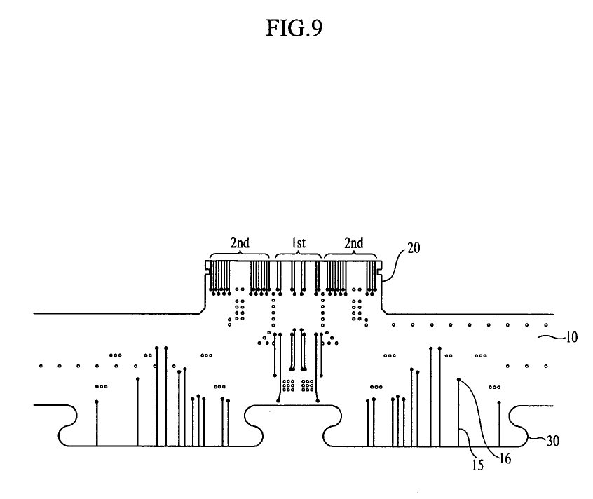

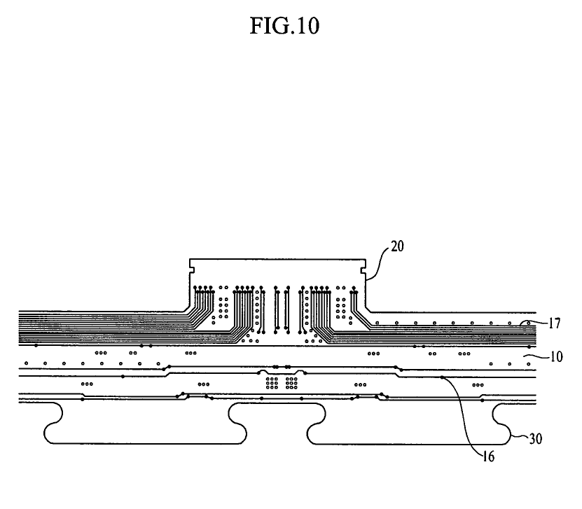

As shown in FIGS. 9 and 10, the first transversal wirings run from the center of the input end (20) to the first longitudinal wirings. A portion of the first transversal wirings run in a layer other than the layer that the other first transversal wirings run, which may be helpful to reduce the resistance in the ground electrode that is formed on the most portion of the layer. As shown in FIGS. 8 and 10, the first longitudinal wirings position closer to the output end (30) than the input end (20).

As shown in FIG. 10, the second transversal wirings are coupled directly to the second longitudinal wirings and are formed on the same layer as the layer that the second longitudinal wirings are formed on. The second transversal wirings are connected to the second longitudinal wirings by inclined wirings. Similar to the embodiment described above, if a wiring is far enough and don't affect other signals transferring other wirings, inclined wirings or curving wirings may be better than perpendicularly bending wirings for signal interference.

The majority of the transversal wirings are formed in the layer shown in FIG. 9. The second transversal wirings, the inclined direction wirings, a portion of the first transversal wirings, first longitudinal wirings and the second longitudinal wirings are formed on the layer shown in FIG. 10.

As shown in FIG. 9, the first transversal wirings and the second transversal wirings are formed on one layer in the input end, which is convenient connecting to 6uter wirings like PCBs.

FIGS. 2 and 5 show an output portion of the FPCF 10. The first and the second longitudinal wirings are electrically connected to the input end 20 and the output end 30 by the transversal wirings. The wirings in the output end are third transversal wirings. The third transversal wirings are electrically coupled to the first and the second longitudinal wirings via holes. The third transversal wirings are formed on a layer different from the layer where the first and the second longitudinal wirings are formed. Thus the ground signal is not divided, and the wirings do not intersect one another. The ground electrode is formed in most areas except where the wirings are formed.

The above described structure of the present embodiment does not integrate the wirings and minimize interferences among wirings in the input portion 20 of the FPCF 10.

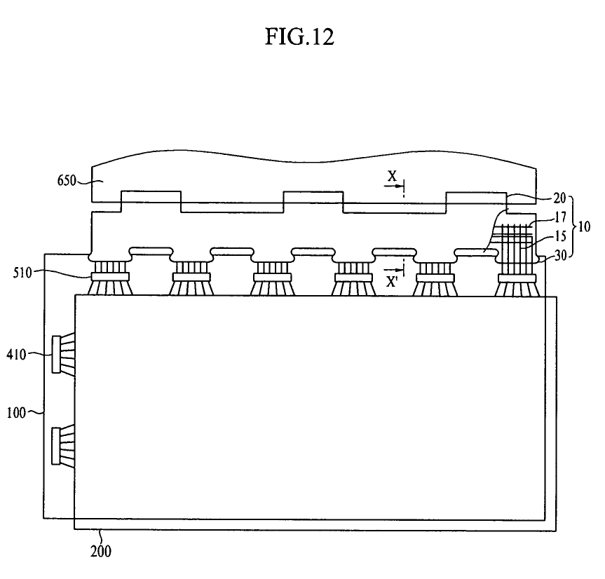

FIG. 12 shows an example that the FPCF is used in a TFT LCD. It is a COG type LCD. The driving ICs 410 and 510 are attached on the lower substrate 100. The driving ICs 410 and 510 are connected to the output end 30 of the FPCF 10. The input end 20 of the FPCF 10 is connected to the PCB 650. The PCB 650 includes control devices (not shown) that control the LCD. The control signals generated from the control devices are transferred to the input end 20 of the FPCF 10 through the PCB 650. The signals transferred to the input end of the FPCF go to the output end 30 through the wirings. The signals transferred to the output end are transferred to the gate IC (410) and/or data IC (510). The signals transferred to the gate IC and data IC control the LCD.

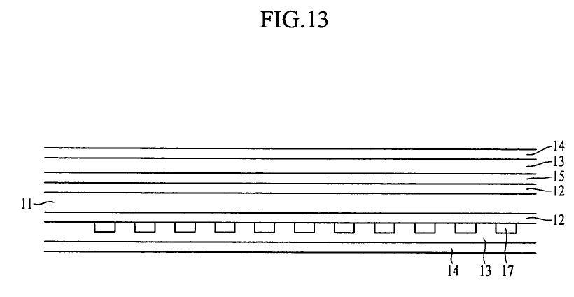

FIG. 13 shows a cross section of an embodiment of the present invention. On both sides of a flexible film 11, the longitudinal wirings 17 and the transversal wiring 15 are formed with the adhesive material 12. An adhesive layer 13 for the protection film 14 is formed on the wirings, and the protection film 14 is formed on the adhesive layer 13.

The flexible film 11 is made of polymers like polyimide. Polyimide is flexible and resist well against heat. The flexible film 11 that is as thick as 12.5 μm˜75 μm is available. If the flexible film 11 is thicker than 50 μm, it becomes less flexible. Therefore 12.5 μm˜50 μm thickness is preferable for a polyimide film, but on the thickness may vary depending on the film material.

The adhesive 12 for wirings is an epoxy group resin or a phenol group resin and is about 10 μm˜20 μm thick, which is almost the same thickness as the wirings 15 and 17.

The wirings are made of metal like copper. The wirings are formed on the adhesive 12. The wirings are formed on both surface of the flexible film on the adhesive 12, and electrically connected to each other through the holes formed in the flexible film.

The wirings 15 and 17 are covered with an insulating film made of polymer, and are exposed at the input end and the output end. Therefore, the FPCF can be electrically coupled to other components.

The insulating film 14 covering the wirings is made of polyimide. The adhesive 13 can be epoxy group, acryl group, or polyester group. The adhesive 13 is as thick as 15 μm˜30 μm. The insulating film 14 is as thick as 7 μm˜15 μm.

The present embodiment shows that the wirings are formed on a film with an adhesive, but the FPCF can be formed without adhesive, and in various ways depending on materials and methods.

An embodiment of the present invention discloses a flexible printed circuit film (FPCF) whose wirings are mostly formed in the transversal and the longitudinal direction of the FPCF. Thus the transversal wirings are intended to be at right angle against the longitudinal wirings. It means that more than 98% of the total wirings are formed in the transversal direction or the longitudinal direction, and the remainders are formed in inclined directions. The wirings intersect each other in different layers. This structure of FPCF can reduces interferences among the signals transferring through the FPCF, even with a higher density of wirings in a smaller area.

It will be apparent to those skilled in the art that various modifications and variations of the present invention can be made without departing from the spirit or scope of the invention. Thus, it is intended that the present invention covers the modifications and variations of the invention including the scope of the appended claims and their equivalents.

1. A flexible printed circuit film, comprising:
a flexible insulating film with multiple layers;
a first wirings formed on one layer of the flexible insulating film in a first direction; and
a second wirings formed on another layer of the flexible insulating film in a second direction;
wherein the first wirings and the second wirings are electrically coupled; and
wherein the first direction is substantially perpendicular to the second direction.

2. The flexible printed circuit film of claim 1, further comprising:
an input portion;
an output portion; and
a connection portion which connects the input portion and the output portion,
wherein the first wirings extend to a transversal direction; and
the second wirings extend to a longitudinal direction.

3. The flexible printed circuit film of claim 2,
wherein the first wirings comprises a first group, a second group and a third group; and
the second wirings comprises a fourth group and a fifth group;
wherein the first group and the second group are formed in the input portion;
wherein the third group is formed in the output portion;
wherein a part of the first group is electrically coupled to a part of the fourth group; and
wherein a part of the second group is electrically coupled to a part of the fifth group.

4. The flexible printed circuit film of claim 3, further comprising:
a first insulating film covering the first wirings; and
a second insulating film covering the second wirings;

5. The flexible printed circuit film of claim 4,
wherein the first insulting film and the second insulating films are attached to the first wiring and the second wiring with adhesive.

6. The flexible printed circuit film of claim 5,
wherein the first insulating films and the second insulting film are made of polymers.

7. The flexible printed circuit film of claim 3,
wherein some of the shorter direction wirings are connected to the longer direction wirings with inclined wirings.

8. The flexible printed circuit film of claim 1,
wherein the first wirings and the second wirings are attached to the flexible film with adhesive.

9. The flexible printed circuit film of claim 1,
wherein the flexible film is made of polyimide.

10. The flexible printed circuit film of claim 3,
wherein the first group formed at the center portion of the input end and the second group is formed at both sides of the first group.

11. The flexible printed circuit film of claim 1,
wherein the second wirings are formed on the other side of the flexible film that the first wirings are formed on.

12. The flexible printed circuit film of claim 11,
wherein the wirings are attached on a flexible film with adhesive.

13. The flexible printed circuit film of claim 2,
wherein the wirings formed in the transversal direction are about 90° from the wirings formed in the longitudinal direction.

14. The flexible printed circuit film of claim 1,
wherein the first wiring and the second wiring are more than 98% of total wirings on the flexible printed circuit film.

15. The flexible printed circuit film of claim 14, further comprising:
a group electrode; and
inclined wirings formed in the direction other than the first direction and the second longer direction; and
wherein the ground electrode is not divided through the whole area of one layer.

16. A method for manufacturing a flexible printed circuit film, comprising:
forming a first wiring on a first layer of a flexible film; and
forming a second wiring on a second layer of the flexible film,
wherein the first wiring extends in a first direction;
the second wiring extents in a second direction; and
the angle between the first wiring and the second wiring is about 90°;
wherein the first wirings are more than 98% of all the wirings formed on the first wirings.

17. The method of claim 16, further comprising:
forming a first insulating film on the first wirings; and
forming a second insulating film on the second wirings,
wherein the first insulating film, the second insulating film, and the flexible film are made of polymer.

18. The method of claim 16,
wherein a portion of the first wirings and a portion of the second wiring are electrically coupled through a hole.

19. The method of claim 16,
wherein only transversal direction wirings are formed on one side of the flexible film.

20. A flexible printed circuit, comprising:
first wirings formed on first layer;
second wirings formed on second layer;
an input portion of wirings that is inputted with signals;
an output portion of wirings that is outputted with signals; and
a connection portion of wirings which connects the input potion and the output portion,
wherein the first wirings extend to the perpendicular direction of the second wirings;
the input portion and the output portion wirings is composed of only the first wirings; and
all of the first wirings is electrically connected to at least a portion of the second wirings.

21. The flexible printed circuit of claim 20, further comprising:
at least two polyimide insulating film to insulate the circuit from circumference.
